(19) United States
(12) Patent Application Publication
(10) Pub. No.: US 2010/0149680 A1
(43) Pub. Date: Jun. 17, 2010

(54) METHOD OF MANUFACTURING MAGNETIC RECORDING MEDIUM, MAGNETIC RECORDING MEDIUM, AND MAGNETIC RECORDING REPRODUCING APPARATUS

(75) Inventors: Shinichi ISHIBASHI, Akishima-shi (JP); Masato FUKUSHIMA, Ichihara-shi (JP); Akira SAKAWAKI, Ichihara-shi (JP)

Correspondence Address: SUGHRUE MION, PLLC, 2100 PENNSYLVANIA AVENUE, N.W., SUITE 800, WASHINGTON, DC, 20037, US

(73) Assignee: SHOWA DENKO K.K., Tokyo (JP)

(21) Appl. No.: 12/634,384

(22) Filed: Dec. 9, 2009

(30) Foreign Application Priority Data
Dec. 10, 2008 (JP) 2008-314957

(51) Int. Cl. G11B 21/02; C23C 16/513; C23C 14/34

(52) U.S. Cl. 360/75; 427/569; 204/192.34

(57) ABSTRACT

The present invention provides a method of manufacturing a magnetic recording medium where at least a magnetic layer is formed on a non-magnetic substrate and a magnetically separated magnetic recording pattern is formed on the magnetic layer, including: a magnetic recording pattern forming process of forming magnetic recording areas that are constructed with convex portions and boundary areas that are constructed with concave portions between the magnetic recording area as the magnetic recording pattern on the magnetic layer; followed by a protective layer forming process of forming a protective carbon layer by using a high-frequency plasma chemical vapor deposition method and by applying a negative bias to the non-magnetic substrate to make the protective carbon layer on the magnetic recording area thinner than the protective carbon layer on the boundary area.

### CROSS-REFERENCE TO RELATED APPLICATIONS

Priority is claimed on Japanese Patent Application No. 2008-314957, filed Dec. 10, 2008, the content of which is incorporated herein by reference.

### BACKGROUND OF THE INVENTION

1. Field of the Invention

The present invention relates to a magnetic recording medium, a method of manufacturing the magnetic recording medium, and a magnetic recording reproducing apparatus.

2. Description of the Prior Art

Recently, since an application range of magnetic recording reproducing apparatuses such as magnetic disk apparatuses, flexible disk apparatuses, and magnetic tape apparatuses has greatly widened, the importance of these apparatuses has further increased. In addition, with respect to magnetic recording mediums used for these apparatuses, greatly improving these recording densities has been attempted. Particularly, from the time that the MR (magneto resistive) heads and PRML (partial response maximum likelihood) technologies were introduced, the surface recording densities have been further improved. Recently, since the GMR (giant magneto resistive) head, the TMR (tunneling magneto resistive) head, and the like are introduced, the surface recording densities continues to be increased by about 50% per year. With respect to the magnetic recording medium, higher recording density thereof will be required. Therefore, a high coercive force of a magnetic layer, a high signal-to-noise ratio (SNR), and a high resolution have been required. In addition, recently, improvement of the surface recording density through an increase in track density at the time of improvement of the linear recording density is still being attempted.

With respect to the recent magnetic recording apparatus, the track density thereof increases up to 110 kTPI. However, as the track density increases, the magnetic recording information of adjacent tracks interferes with each other. Therefore, there is a problem in that a magnetization transition area in the boundary area therebetween becomes a noise source to deteriorate the SNR. Since this problem directly leads to deterioration in the bit error rate, the problem blocks the improvement of the recording density.

In order to increase the surface recording density, there is a need to ensure saturated magnetization and thickness of the magnetic layer as much as possible by reducing the size of each recording bit on the magnetic recording medium. However, as the recording bit is reduced, the minimum magnetization volume per one bit becomes small, such that there is a problem in that the recording data disappear due to the magnetization inversion caused by thermal fluctuation.

In addition, since a distance between the tracks is decreased along with the increase in the surface recording density, the magnetic recording apparatus requires a highly accurate track servo technology, and at the same time, in order to perform recording in a wide scale and remove influence of adjacent track in the reproduction as much as possible, a method of performing the reproduction in a narrower scale than the recording time has been generally used. However, in the method, the influence between the adjacent tracks can be suppressed to a minimum, but it is difficult to obtain sufficient reproduction output. For this reason, there is a problem in that it is difficult to ensure a sufficient SNR.

As one of the methods of solving the aforementioned thermal fluctuation problem or ensuring the SNR or the sufficient output, a technology of improving the track density by forming convex-concave portion on a surface of the magnetic recording medium along the tracks and physically separating the recording tracks has been attempted. Hereinafter, this technology is referred to as a discrete track method, and a magnetic recording medium manufactured according to the method is referred to as a discrete track medium.

In addition, a technology of manufacturing a so-called patterned medium in which a data track area in the same track is further divided has been attempted.

As an example of the aforementioned discrete track medium, there is known a magnetic recording medium which is formed by using a non-magnetic substrate where a convex-concave pattern is formed on a surface thereof and in which physically separated magnetic recording tracks and servo signal patterns are formed (for example, refer to Patent Document 1). In the magnetic recording medium disclosed in Patent Document 1, a ferromagnetic layer is formed through a soft magnetic layer on a surface of the substrate where a plurality of the convex-concave portions exists on the surface thereof, and a protective layer is formed on a surface of the ferromagnetic layer. In the convex area, a magnetic recording area that is physically separated from the surroundings is formed. According to the magnetic recording medium disclosed in Patent Document 1, since the occurrence of magnetic walls in the soft magnetic layer can be suppressed, the influence of the thermal fluctuation does not easily occur. In addition, since there is no interference between adjacent signals, it is considered that a high-density magnetic recording medium having small noise can be obtained.

In addition, as an example of the aforementioned discrete track method, there is a method of forming the tracks after forming a magnetic recording medium of which layers are formed as thin films or a method of performing a magnetic recording medium thin film formation directly on a surface of a substrate in advance or after forming a convex-concave pattern on a thin film layer for track formation (for example, refer to Patent Documents 2 and 3).

In addition, there have been proposed methods of changing magnetic characteristics of the areas between magnetic tracks in the discrete track medium by injecting nitrogen or oxygen ions into a magnetic layer that is formed in advance or by irradiating a laser on the magnetic layer (for example, refer to Patent Documents 4 to 6)

Patent Document 1: Japanese Unexamined Patent Application Publication No. 2004-164692

Patent Document 2: Japanese Unexamined Patent Application Publication No. 2004-178793

Patent Document 3: Japanese Unexamined Patent Application Publication No. 2004-178794

Patent Document 4: Japanese Unexamined Patent Application Publication No. H5-205257

Patent Document 5: Japanese Unexamined Patent Application Publication No. 2006-209952

Patent Document 6: Japanese Unexamined Patent Application Publication No. 2006-309841

### SUMMARY OF THE INVENTION

As the aforementioned method of manufacturing a so-called discrete track medium or a patterned medium having the magnetically separated magnetic recording pattern, there is a method of forming the magnetic recording pattern by irradiating the magnetic layer with reactive plasma or reactive ions using oxygen or halogen. In addition, there is a method of processing a layer having the magnetic recording medium by performing the ion injection into the magnetic layer. Hereinafter, these methods are referred to as a magnetic layer reforming method.

In the method using the aforementioned magnetic layer reforming method, for example, first, after a mask layer is formed on a surface of the magnetic layer, the mask layer is patterned by using a photolithography technology. Next, by performing an ion injection or the like on the boundary areas of the magnetic recording pattern, a magnetic recording pattern in which the magnetic characteristics on the areas are deteriorated or become nonmagnetic is formed, thereby manufacturing the discrete track medium or patterned medium.

In comparison with a manufacturing method (hereinafter, referred to as a magnetic layer processing method) where the magnetic layer is physically processed to bury a non-magnetic material in the boundary area and, after that, the surface thereof is smoothed, the magnetic layer reforming method has advantages in that the manufacturing processes can be simplified and the influence of contaminants on the processing product in the manufacturing processes can be reduced.

On the other hand, in the magnetic layer formed by the magnetic layer reforming method, the boundary areas that are formed by performing partial ion irradiation and ion injection on the continuous magnetic layer are cut by an etching function. Therefore, a step difference of convex-concave portions may occur on the surface between the magnetic recording areas and the boundary areas in the vicinity thereof, and the step difference may be introduced to the protective layer or the like formed thereon. If the step difference occurs on the surface of the magnetic recording medium, the float property of the magnetic head may be unstable, thereby causing a problem in that, for example, errors occur during the recording reproducing.

In order to prevent the problem of the aforementioned step difference, for example, a process of smoothing the surface by filling the concave portion of the step difference portion with a different material may be used. However, in the case where the process is used, there is a problem in that the aforementioned advantages of the magnetic layer reforming method such as the simplification of the manufacturing processes cannot be obtained.

The present invention was conceived in view of the above-described circumstances, and an objective of the present invention is to provide a method of manufacturing a magnetic recording medium capable of producing a magnetic recording medium having an excellent surface smoothness with a high productivity.

Another objective of the present invention is to provide a magnetic recording medium that is manufactured by a manufacturing method according to the present invention, capable of ensuring excellent recording reproducing characteristics and being adapted to a high recording density.

Another objective of the present invention is to provide a magnetic recording reproducing apparatus, including a magnetic recording medium according to the present invention, having an excellent high-recording density characteristic.

The inventors have contrived the formation of a magnetic recording pattern by simultaneously using the aforementioned magnetic layer reforming method and magnetic layer processing method in order to manufacture the magnetic recording medium capable of being adapted to the high recording density. In other words, first, after the patterned mask layer is formed on the surface of the continuous magnetic layer, the upper portion of the magnetic layer at the portion which is not covered with the mask pattern is removed by the ion milling, and the ion injection is performed on the lower layer of the portion, thereby reforming the magnetic characteristic. In comparison with the magnetic recording pattern that is formed by the magnetic layer processing method, in the magnetic recording pattern that is formed by the above method, the convex-concave portion on the surface is small. However, since the convex-concave portion is still formed on the surface of the magnetic layer, there is a need to smooth the surface by burying the non-magnetic material or the like in the concave portion.

The inventors have further researched the smoothing process. As a result, it has been discovered that the carbon layer on the convex portion of the magnetic layer can be formed to be thinner than the carbon layer on the concave portion by forming the carbon layer by using a high-frequency plasma chemical vapor deposition method and by applying a negative bias to the substrate. Accordingly, the surface of the magnetic recording pattern can be smoothed, and the carbon layer is directly used as a protective layer of the magnetic recording medium, and thus the manufacturing processes for the magnetic recording medium can be greatly simplified, as a result, the present invention is achieved.

In other words, the present invention employs the following configurations.

[1] A method of manufacturing a magnetic recording medium where at least a magnetic layer is formed on a non-magnetic substrate and a magnetically separated magnetic recording pattern is formed on the magnetic layer, including: a magnetic recording pattern forming process of forming magnetic recording areas that are constructed with convex portions and boundary areas that are constructed with concave portions between the magnetic recording areas as the magnetic recording pattern on the magnetic layer; followed by a protective layer forming process of forming a protective carbon layer using a high-frequency plasma chemical vapor deposition method while applying a negative bias to the non-magnetic substrate to make the protective carbon layer on the magnetic recording area thinner than the protective carbon layer on the boundary area.

[2] The method of manufacturing a magnetic recording medium according to [1], wherein a boundary area reforming process of oxidizing or nitriding a surface of the boundary area is included between the magnetic recording pattern forming process and the protective layer forming process.

[3] The method of manufacturing a magnetic recording medium according to [1] or [2], wherein in the magnetic recording pattern forming process, the boundary area is formed as a non-magnetic area.

[4] The method of manufacturing a magnetic recording medium according to any one of [1] to [3], wherein in the magnetic recording pattern forming process, the boundary area is formed by performing ion milling and ion injection on the magnetic layer.

[5] The method of manufacturing a magnetic recording medium according to any one of [1] to [4], wherein in the magnetic recording pattern forming process, a step difference of a convex-concave portion between the magnetic recording area and the boundary area is formed in a range of 0.1 to 9 nm.

[6] The method of manufacturing a magnetic recording medium according to any one of [1] to [5], wherein in the protective layer forming process, a step difference of a convex-concave portion between the magnetic recording area and the boundary area on a surface of the protective carbon layer is formed in a range of 0 to 11 nm.

[7] A magnetic recording medium manufactured by the method of manufacturing a magnetic recording medium according to any one of [1] to [6].

[8] A magnetic recording reproducing apparatus comprising: the magnetic recording medium according to [7]; a driving unit that drives the magnetic recording medium in a recording direction; a magnetic head that is constructed with a recording unit and a reproducing unit; a means for relatively moving the magnetic head with respect to the magnetic recording medium; and a recording reproducing signal processing means for inputting signals to the magnetic head and reproducing signals output from the magnetic head.

In the method of manufacturing the magnetic recording medium according to the present invention, since the method is a method including the magnetic recording pattern forming process of forming the magnetic recording areas that are constructed with the convex portions and the boundary areas that are constructed with the concave portions between the magnetic recording areas as the magnetic recording pattern on the magnetic layer, followed by the protective layer forming process of forming the protective carbon layer using the high-frequency plasma chemical vapor deposition method while applying a negative bias to the non-magnetic substrate to make the protective carbon layer on the magnetic recording area thinner than the protective carbon layer on the boundary area, the convex-concave portions formed on the magnetic recording pattern can be efficiently smoothed. In addition, since the protective carbon layer used for the smoothing is also used as the protective layer of the magnetic recording medium, it is possible to greatly simplify the manufacturing processes. Therefore, it is possible to manufacture the magnetic recording medium having an excellent surface smoothness with a high productivity.

In addition, since the magnetic recording medium according to the present invention is a magnetic recording medium that can be obtained by the manufacturing method according to the present invention, sufficient recording reproducing characteristics can be obtained, such that it is possible to implement the magnetic recording medium that can be adapted to a high recording density.

In addition, since the magnetic recording reproducing apparatus according to the present invention includes the magnetic recording medium of the present invention, it is possible to implement a magnetic recording reproducing apparatus having excellent high-recording density characteristics.

If the method of manufacturing the magnetic recording medium according to the present invention is adapted to a process of manufacturing the magnetic recording medium that is used for a magnetic recording reproducing apparatus, that is, a hard disk drive, it is possible to manufacture a magnetic recording medium having excellent electro-magnetic conversion characteristics with a high productivity, and a great number of industrial uses become available.

### BRIEF DESCRIPTION OF THE DRAWINGS

FIG. 1A is a diagram schematically showing the method of manufacturing a magnetic recording medium according to the present invention, specifically is a process drawing illustrating Process A at the time of forming layers on a non-magnetic substrate.

FIG. 1B is a diagram schematically showing the method of manufacturing a magnetic recording medium according to the present invention, specifically is a process drawing illustrating Process B at the time of forming layers on a non-magnetic substrate.

FIG. 1C is a diagram schematically showing the method of manufacturing a magnetic recording medium according to the present invention, specifically is a process drawing illustrating Process C at the time of forming layers on a non-magnetic substrate.

FIG. 2A is a diagram schematically showing the method of manufacturing a magnetic recording medium according to the present invention, specifically is a process drawing illustrating Process D at the time of forming layers on a non-magnetic substrate.

FIG. 2B is a diagram schematically showing the method of manufacturing a magnetic recording medium according to the present invention, specifically is a process drawing illustrating Process E at the time of forming layers on a non-magnetic substrate.

FIG. 2C is a diagram schematically showing the method of manufacturing a magnetic recording medium according to the present invention, specifically is a process drawing illustrating Process F at the time of forming layers on a non-magnetic substrate.

FIG. 3A is a diagram schematically showing the method of manufacturing a magnetic recording medium according to the present invention, specifically is a process drawing illustrating Process G at the time of forming layers on a non-magnetic substrate.

FIG. 3B is a diagram schematically showing the method of manufacturing a magnetic recording medium according to the present invention, specifically is a process drawing illustrating Process H at the time of forming layers on a non-magnetic substrate.

FIG. 3C is a diagram schematically showing the method of manufacturing a magnetic recording medium according to the present invention, specifically is a process drawing illustrating Process I at the time of forming layers on a non-magnetic substrate.

FIG. 4A is a diagram schematically showing an example of forming a protective carbon layer on a magnetic layer formed by the method of manufacturing a magnetic recording medium of the present invention using various layer-forming methods.

FIG. 4B is a diagram schematically showing an example of forming a protective carbon layer on a magnetic layer formed by the method of manufacturing a magnetic recording medium of the present invention using various layer-forming methods.

FIG. 4C is a diagram schematically showing an example of forming a protective carbon layer on a magnetic layer formed by the method of manufacturing a magnetic recording medium of the present invention using various layer-forming methods.

FIG. 5 is a schematic diagram illustrating a magnetic recording reproducing apparatus where the magnetic recording medium according to the present invention is used.

The reference symbols shown in these figures are defined as follows: 1 . . . non-magnetic substrate, 2 . . . magnetic layer, 21 . . . magnetic recording areas (convex portion), 21a . . . surface (magnetic recording area), 22 . . . boundary area (concave portion), 22a . . . surface (boundary area), 9 . . . protective carbon layer, 9a . . . protective carbon layer (protective carbon layer on the magnetic recording area), 9b . . . protective carbon layer (protective carbon layer on the boundary area), 91 . . . surface (protective carbon layer), 10 . . . magnetic recording medium, 20 . . . magnetic recording pattern, 50 . . . magnetic recording reproducing apparatus, 51 . . . medium driving unit (driving unit driving the medium in a recording direction), 57 . . . magnetic head, 58 . . . head driving unit (means for relatively moving the magnetic head with respect to the magnetic recording medium), 59 . . . recording reproducing signal system (means for treating the recording reproducing signal)

### DETAILED DESCRIPTION OF THE PREFERRED EMBODIMENT

Hereinafter, exemplary embodiments of a method of manufacturing a magnetic recording medium, a magnetic recording medium, and a magnetic recording reproducing apparatus according to the present invention will be described with reference to the drawings.

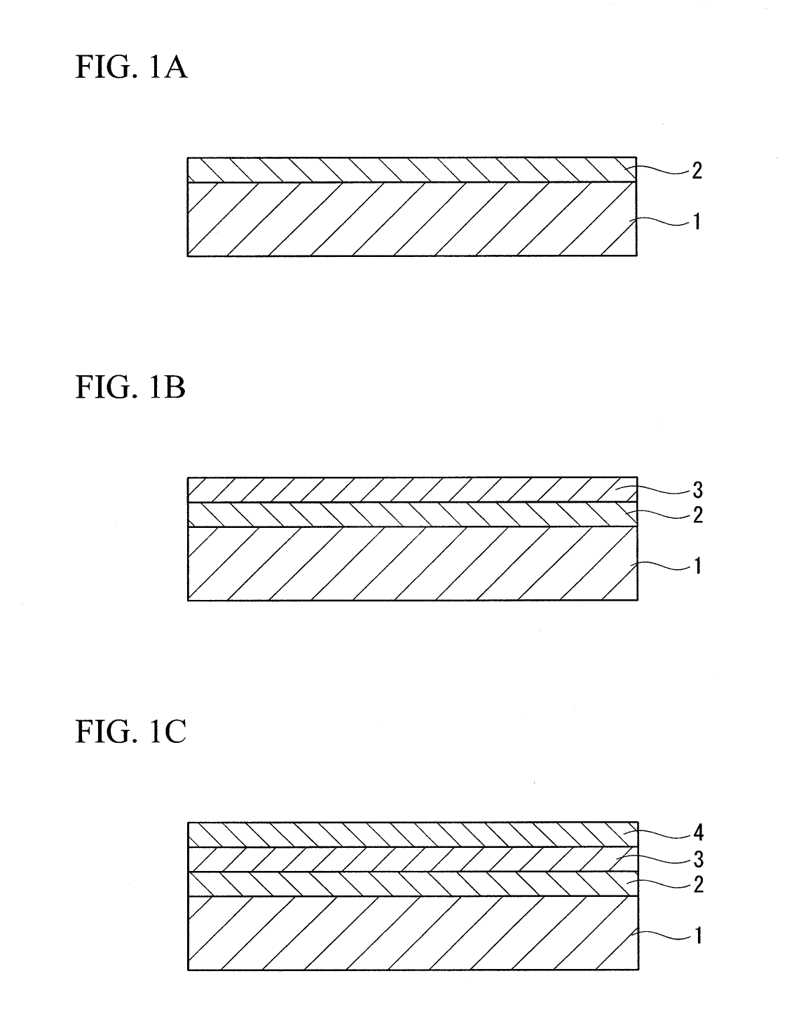

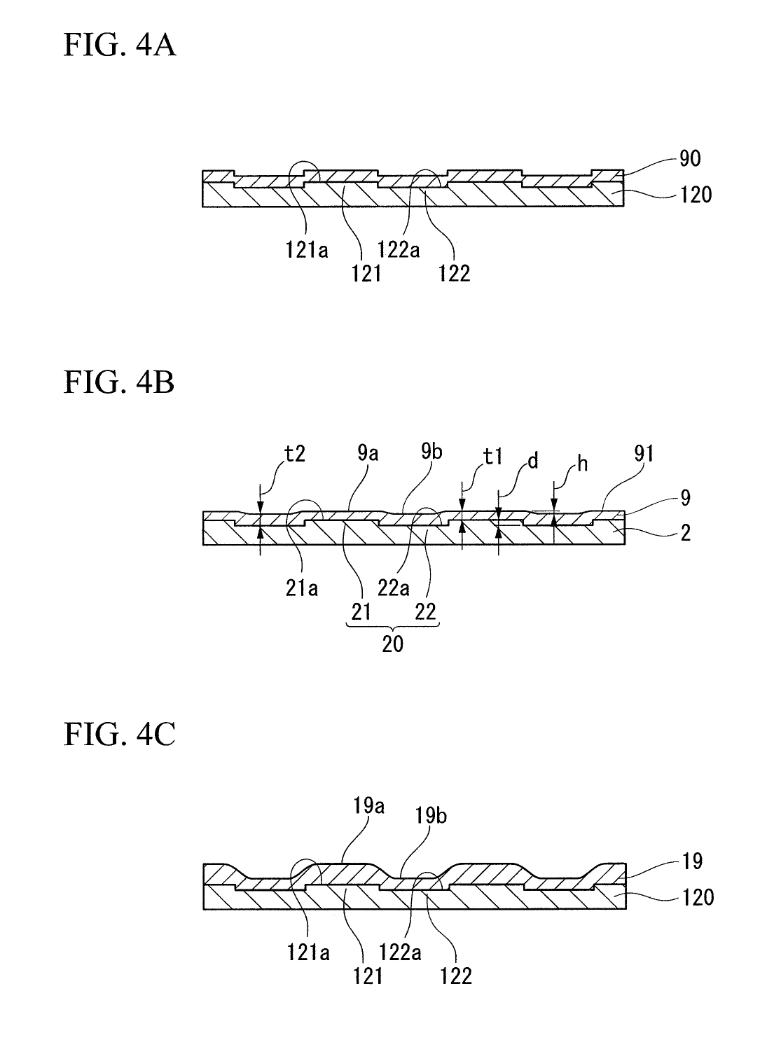

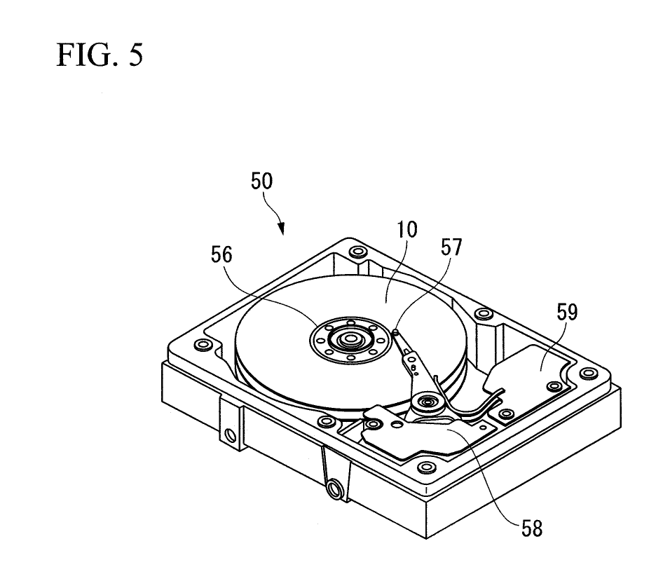

FIGS. 1A to 1C, FIGS. 2A to 2C, and FIGS. 3A to 3C are diagrams schematically showing the method of manufacturing a magnetic recording medium according to the embodiment. FIGS. 4A to 4C are diagrams schematically showing examples of forming a protective carbon layer on a magnetic layer. FIG. 5 is a schematic diagram showing an example of a magnetic recording reproducing apparatus provided with the magnetic recording medium according to the embodiment. In addition, the drawings referred to in the description hereinafter are the drawings for explaining the method of manufacturing the magnetic recording medium, the magnetic recording medium, and the magnetic recording reproducing apparatus. In the drawings, the size, thickness, and dimensions of each element shown are different from the real dimensional relationship of the magnetic recording medium or the like.

The method of manufacturing the magnetic recording medium according to the present invention is a method of forming at least a magnetic layer 2 on a non-magnetic substrate 1 and forming a magnetically separated magnetic recording pattern 20 on the magnetic layer 2. The method includes a magnetic recording pattern forming process of forming magnetic recording areas 21 that are constructed with convex portions and boundary areas 22 that are constructed with concave portions between the magnetic recording areas 21 as the magnetic recording pattern 20 on the magnetic layer 2 and a protective layer forming process of forming a protective carbon layer 9 by using a high-frequency plasma chemical vapor deposition method and by applying a negative bias to the non-magnetic substrate 1 to make a protective carbon layer 9a on the magnetic recording area 21 thinner than a protective carbon layer 9b on the boundary area 22.

[Magnetic Recording Medium]

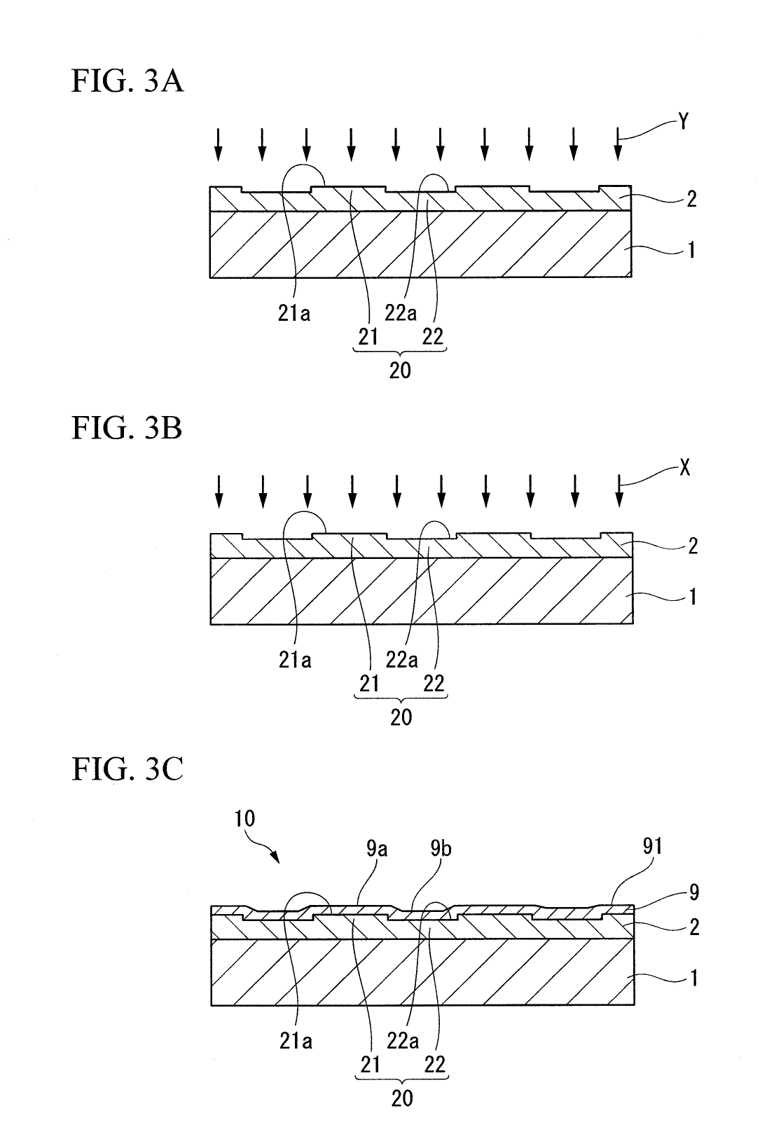

A magnetic recording medium 10 that is manufactured by using the manufacturing method according to the embodiment is described in detail with reference to the process views shown in FIGS. 1A to 1C, FIGS. 2A to 2C, and FIGS. 3A to 3C and the diagrammatic cross-sectional views shown in FIGS. 4A to 4C. The views of FIGS. 1A to 1C, FIGS. 2A to 2C, and FIGS. 3A to 3C are schematic views showing the processes for manufacturing the magnetic recording medium 10 by forming each layer on the non-magnetic substrate 1. Among the figures, FIG. 3C is a cross-sectional view showing a lamination structure of the magnetic recording medium 10 manufactured by the processes. In addition, FIGS. 4A to 4C are diagrammatic views for explaining an example of forming the protective carbon layer on the magnetic layer by using various layer forming methods. Among the figures, FIG. 4B is a cross-sectional view showing main elements of the magnetic recording medium 10 according to the present invention where the protective carbon layer 9 is formed by using a high-frequency plasma chemical vapor deposition method and by applying a negative bias to the non-magnetic substrate 1.

In the magnetic recording medium 10 according to the embodiment, the magnetically separated magnetic recording pattern 20 is formed on the non-magnetic substrate 1, and the magnetic recording medium 10 has a shape of substantially a doughnut plate as viewed in plane (refer to reference numeral 10 shown in a magnetic recording reproducing apparatus 50 in FIG. 5).

In addition, the magnetic recording pattern described in the present invention includes a so-called patterned medium where a magnetic recording pattern is arranged with a predetermined regularity per one bit and a medium where the magnetic recording pattern is arranged in a track shape, and also includes a medium including a servo signal pattern or the like. Among them, the method of manufacturing the magnetic recording medium according to the present invention and the magnetic recording medium are very suitably adapted to a so-called discrete type magnetic recording medium where the magnetically separated magnetic recording pattern is constructed with magnetic recording tracks and servo signal patterns in terms of simplification of the manufacturing processes.

The magnetic recording medium 10 according to the embodiment is schematically configured to have, for example, a structure where a soft magnetic layer, an intermediate layer, a magnetic layer 2 formed in a magnetic pattern, and a protective carbon layer 9 are laminated on a surface of the non-magnetic substrate 1, and where a lubricating layer is further formed on an uppermost surface thereof. In addition, in the magnetic recording medium according to the present invention, layers except for the non-magnetic substrate 1, the magnetic layer 2, and the protective carbon layer 9 may be appropriately provided. Therefore, in the example shown in FIG. 3C, the layer except for the non-magnetic substrate 1, the magnetic layer 2, and the protective carbon layer 9 constituting the magnetic recording medium 10 are not shown.

In addition, the magnetic recording medium 10 is a discrete track medium having the magnetic layer 2 of which magnetization is directed in the perpendicular direction of the non-magnetic substrate 1. Information signals are written in or read from the magnetic recording pattern 20 by a magnetic head 57 having a reading head and a writing head (refer to a magnetic recording reproducing apparatus 50 shown in FIG. 5).

An Al ally substrate containing AL as a main constituent such as an Al—Mg alloy, a substrate made of a general soda glass, an alumina silicate series glass, a crystalline glass, silicon, titan, ceramics, or various resins, or an arbitrary non-magnetic substrate may be used as the non-magnetic substrate 1. Among the above substrates, the Al alloy substrate, the glass series substrate made of such a crystalline glass, or the silicon substrate may be preferably used.

In addition, an average surface roughness (Ra) of the non-magnetic substrate 1 made of such a material is preferably 1 nm or less, more preferably 0.5 nm or less, most preferably 0.1 nm or less.

In the magnetic recording medium 10 according to the embodiment, a soft magnetic layer or intermediate layer (not shown) may be appropriately provided between the aforementioned non-magnetic substrate 1 and the later-described magnetic layer 2. The soft magnetic layer and the intermediate layer appropriately employ a material and structure that have been used in the field of the magnetic recording medium.

The soft magnetic layer may be formed by using a soft magnetic material such as a FeCo series alloy (FeCoB, FeCoSiB, FeCoZr, FeCoZrB, FeCoZrBCu, or the like), a FeTa series alloy (FeTaN, FeTaC, or the like), a Co series alloy (CoTaZr, CoZrNB, CoB, or the like). In addition, the intermediate layer may be formed by using, for example, a Ru layer or the like.

The magnetic layer 2 is a layer that is formed on the non-magnetic substrate 1 or on a surface of the aforementioned soft magnetic layer or intermediate layer that is appropriately provided. For example, the magnetic layer 2 may be formed in a single layer or a laminated structure of two or more layers. Although the magnetic layer 2 may be configured as an in-plane magnetic layer or a perpendicular magnetic layer, the perpendicular magnetic layer is preferable in order to implement a higher recording density.

A material containing an oxide in a range of 0.5 to 6 atom % is preferably used for the magnetic layer 2, and in addition, the magnetic layer 2 is preferably configured with an alloy containing Co as a main constituent. In the embodiment, the magnetic layer 2 may be formed by using, for example, an alloy formed by adding an oxide to CoCr, CoCrPt, CoCrPtB, CoCrPtB—X, or CoCrPtB—X—Y or a Co series alloy such as CoCrPt-O, CoCrPt—SiO₂, CoCrPt—Cr₂O₃, CoCrPt—TiO₂, CoCrPt—ZrO₂, CoCrPt—Nb₂O₅, CoCrPt—Ta₂O₅, CoCrPt—Al₂O₃, CoCrPt—B₂O₃, CoCrPt—WO₂, and CoCrPt—WO₃. In addition, in the constituent materials, X denotes Ru, W, or the like, and Y denotes Cu, Mg, or the like.

The thickness of the magnetic layer 2 needs to be a predetermined value or more in order to obtain an output having a certain intensity or more at the reproduction time. On the other hand, parameters as indicators of the recording reproducing characteristics generally deteriorate as the intensity of the output increases. Because of this point, the magnetic layer 2 needs to be formed to have an optimal thickness so as to obtain sufficient head input output characteristics by taking into consideration the type of a used magnetic alloy and a lamination structure. More specifically, the thickness of the magnetic layer 2 is preferably 3 nm or more and 20 nm or less, more preferably 5 nm or more and 15 nm or less.

A magnetic recording pattern 20 including magnetic recording areas 21 that are constructed with convex portions and boundary areas 22 that are constructed with concave portions between the magnetic recording areas 21 is disposed on the magnetic layer 2 according to the embodiment.

The magnetic recording area 21 described in the present invention is an area on which the magnetic recording reproducing of various signals is performed by the magnetic head 57 included in the later-described magnetic recording reproducing apparatus 50 (refer to FIG. 5).

In addition, the boundary area 22 described in the present invention is an area for magnetically separating the aforementioned magnetic recording area 21. The coercive force of the boundary area 22 is preferably lower than that of the magnetic recording area 21, more preferably configured as a non-magnetic area. The boundary area 22 is formed, for example, by reforming magnetic characteristics through ion injection into the magnetic layer 2. In addition, the boundary area 22 may be configured by filling positions cut by ion milling with carbon as a non-magnetic material. In addition, the boundary area 22 may be configured as an area of which the surface 22a is oxidized or nitrided.

In the magnetic layer 2, it is preferable that a step difference of the convex-concave portion between the magnetic recording area 21 constructed with the convex portion and the boundary area 22 constructed with the concave portion is in a range of 0.1 to 9 nm. If the step difference between the magnetic recording area 21 and the boundary area 22 is in the range, the protective carbon layer 9 that is formed on the magnetic layer 2 according to the later-described manufacturing method can be formed as a layer having an excellent surface smoothness.

The protective carbon layer 9 is formed on the magnetic layer 2 by using, for example, a carbonic layer such as a carbon (C) such as a diamond-like carbon, a hydrocarbon (HₓC), a carbon nitride (CN), an amorphous carbon, and carbon silicate (SiC) or a material generally used as a protective layer such as SiO₂, Zr₂O₃, and TiN. In addition, the protective carbon layer 9 may be formed in a single layer or a laminated structure of two or more layers.

It is preferable that a thickness of the protective carbon layer 9 (refer to reference numerals t1 and t2 shown in FIG. 4B) is less than 10 nm. If the thickness of the protective layer exceeds 10 nm, a distance between the magnetic head (refer to reference numeral 57 shown in FIG. 5) and the magnetic layer 2 increases. Therefore, there is a problem in that input and output signals with sufficient intensities may not be obtained.

In addition, in the surface 91 of the protective carbon layer 9, the step difference of a convex-concave portion (refer to reference numeral h shown in FIG. 4C) between the magnetic recording area 21 and the boundary area 22 is in a range of 0 to 11 nm. If the convex-concave portion of the surface 91 of the protective carbon layer 9 is in this range, the protective carbon layer 9 can be formed as the layer having an excellent surface smoothness, as a result, the float property of the magnetic head is improved at the magnetic recording and reproducing time using the magnetic recording medium 10.

As shown in FIG. 3C, with respect to the protective carbon layer 9 according to the embodiment, in the magnetic layer 2 which is configured to include the magnetic recording area 21 constructed with the convex portion and the boundary area 22 constructed with the concave portion, the protective carbon layer 9 (9a) at the position on the magnetic recording area 21 is formed to be thinner than the protective carbon layer 9 (9b) on the boundary area 22 (refer to reference numerals t1 and t2 shown in FIG. 4B).

In general, as described in the later-described manufacturing method, when the magnetic layer of the magnetic recording medium is reformed into a non-magnetic area by ion injection or the like, the boundary area is etched by the etching operation. Therefore, on the magnetic layer, the magnetic recording areas are formed in a convex shape, and the boundary areas are formed in a concave shape between the magnetic recording areas. Accordingly, the surface of the magnetic layer has a convex-concave portion shape, and thus, the surface of the protective layer formed on the magnetic layer also has a convex-concave portion shape. In this manner, in the case where the large convex-concave portions are formed on the surface of the magnetic recording medium and the surface having a low smoothness is formed, for example, the float property of the magnetic head is unstable. Therefore, there may be a problem in that errors occur at the recording reproducing time.

Since the protective carbon layer 9 according to the embodiment is formed by the later-described manufacturing method according to the embodiment, the protective carbon layer 9a located on the magnetic recording area 21 is formed to be thinner than the protective carbon layer 9b located on the boundary area 22. Therefore, occurrence of a height difference between the protective carbon layer 9a located on the magnetic recording area 21 and the protective carbon layer 9b located on the boundary area 22 is suppressed. Accordingly, the surface smoothness is excellent, the float property of the magnetic head is stable, and the recording reproducing properties are sufficiently ensured, thereby obtaining a magnetic recording medium 10 which is adapted to a high recording density.

In addition, in the magnetic recording medium 10 according to the embodiment, it is preferable that a lubricating layer (not shown) is further formed on the protective carbon layer 9. As a lubricant used for the lubricating layer, there are a fluoride series lubricant, a hydrocarbon series lubricant, and a mixture thereof. In addition, the lubricating layer is generally formed to have a thickness of 1 to 4nm.

Due to the aforementioned configuration, the magnetic recording medium 10 is configured to perform magnetic recording or reproducing in the magnetic recording pattern 20 by the magnetic head (refer to a magnetic head 57 in the magnetic recording reproducing apparatus 50 shown in FIG. 5). Since the magnetic recording medium 10 according to the embodiment can be obtained by the following manufacturing method according to the present invention, an excellent surface smoothness can be obtained, sufficient recording reproducing characteristics can be ensured, and the magnetic recording medium 10 can be adapted to a high recording density.

[Method of Manufacturing Magnetic Recording Medium]

Hereinafter, a method of manufacturing a magnetic recording medium will be described in detail with reference to FIGS. 1A to 1C, FIGS. 2A to 2C, and FIGS. 3A to 3C.

As described above, the method of manufacturing the magnetic recording medium 10 according to the embodiment is a method of forming at least a magnetic layer 2 on a non-magnetic substrate 1. The method includes a magnetic recording pattern forming process of forming magnetic recording areas 21 that are constructed with convex portions and boundary areas 22 that are constructed with concave portions between the magnetic recording areas 21 as the magnetic recording pattern 20 on the magnetic layer 2, followed by a protective layer forming process of forming a protective carbon layer 9 using a high-frequency plasma chemical vapor deposition method and while applying a negative bias to the non-magnetic substrate 1 to make a protective carbon layer 9a on the magnetic recording area 21 thinner than a protective carbon layer 9b on the boundary area 22.

In the method of manufacturing the magnetic recording medium according to the present invention, the occurrence of a convex-concave portion on the surface is suppressed according to the method, therefore it is possible to manufacture a magnetic recording medium having an excellent surface smoothness.

[Manufacturing Processes]

Hereinafter, processes included in the method of manufacturing a magnetic recording medium 10 according to the embodiment are described in detail sequentially.

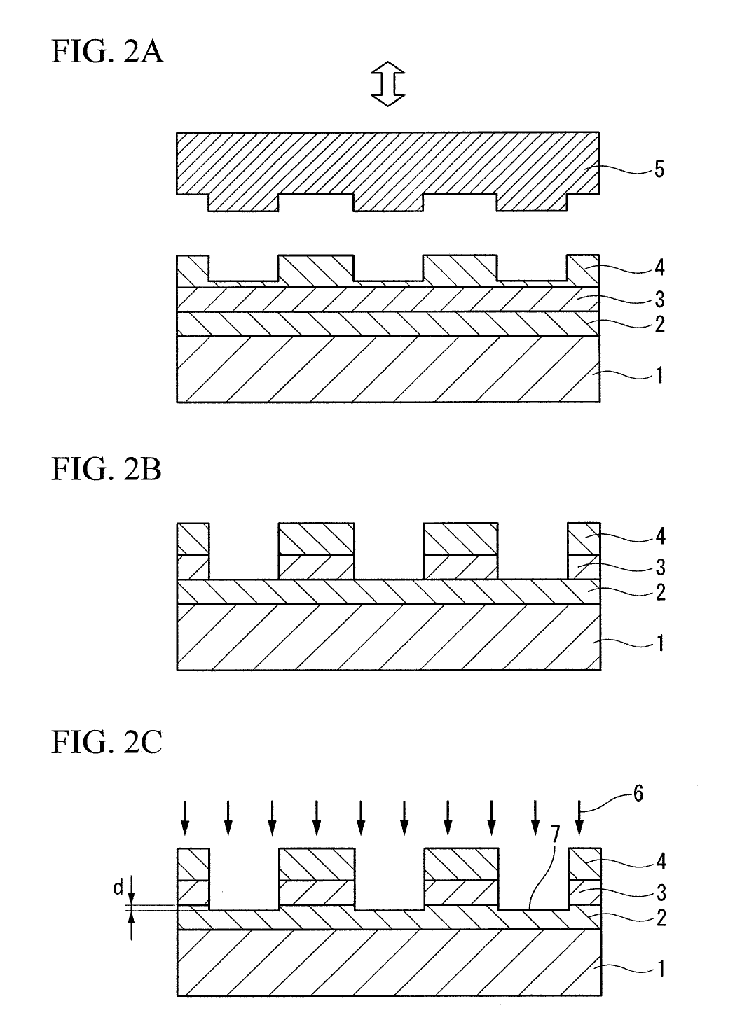

In the embodiment, as shown in FIGS. 1 A to 1C, FIGS. 2A to 2C, and FIGS. 3A to 3C, the magnetic recording medium 10 can be manufactured by a method including: Process A of at least a magnetic layer 2 on a non-magnetic layer 1 (FIG. 1A); Process B of forming a mask layer 3 on the magnetic layer 2 (FIG. 1B); Process C forming a resist layer 4 on the mask layer 3 (FIG. 1C); Process D of transferring a negative pattern (a concave portion corresponding to the magnetic recording area formed on the resist layer in order to separate the magnetic recording area) of the magnetic recording pattern 20 to the resist layer 4 by using the stamp 5 (FIG. 2A, the arrow in the figure indicating a motion of the stamp 5); Process E of removing the mask 8 in a portion corresponding to the negative pattern of the magnetic recording pattern 20 (FIG. 2B, in the case where a remaining portion 4a of the resist layer 4 remains in Process D, the resist layer and the mask are removed); Process F of performing partial ion milling on the superficial layer portion of the magnetic layer 2 from the surface of the resist layer 4 (FIG. 2C, reference numeral 6 denotes the ion milling, reference numeral 7 denotes the portion that is subjected to the partial ion milling in the magnetic layer 2, and reference numeral d denotes a depth of the portion that is subjected to the ion milling in the magnetic layer 2); Process G of removing the resist layer 4 and the mask layer 3 by using a dry etching gas Y after the ion injection is sequentially performed on the portion of the magnetic layer 2 which is removed by the ion milling (FIG. 3A); Process H of oxidizing or nitriding the surface of the magnetic layer 2 by irradiating the surface with oxygen ions or nitrogen ions (FIG. 3B, reference numeral X denotes the oxygen ions or the nitrogen ions); and Process I of covering the surface of the magnetic layer 2 with a protective carbon layer 9 (FIG. 3C) in this order of the processes.

In addition, in the above processes, each of Processes A to G constitutes the aforementioned magnetic recording pattern forming process, and Process I is the protective layer forming process. In addition, in the example described as the embodiment, a boundary area reforming process (Process H) of oxidizing or nitriding the surface of the boundary area 22 may be provided between Process G and Process I, that is, between the magnetic recording pattern forming process and the protective layer forming process.

Process A

First, a soft magnetic layer or intermediate layer (not shown) is formed on the non-magnetic substrate 1 by using a well-known material and method in the related art if needed.

Next, as shown in Process A of FIG. 1A, the magnetic layer 2 that is made of the aforementioned material is formed on the non-magnetic substrate 1 or the soft magnetic layer or intermediate layer. The magnetic layer 2 is generally formed as a thin film by using a sputtering method.

Process B

Next, in Process B shown in FIG. 1B, a mask layer 3 is formed on the magnetic layer 2. It is preferable that the mask layer 3 is made of a material including one or more selected from a group consisting of C, Ta, W, Ta nitride, W nitride, Si, SiO₂, Ta₂O₅, Re, Mo, Ti, V, Nb, Sn, Ga, Ge, As, and Ni. By using such materials, a masking property of the mask layer 3 with respect to milling ions 6 can be improved, and the magnetic recording pattern forming characteristic can be improved by the mask layer 3. In addition, since such materials can be easily subjected to a dry etching process using reactive ions, residual materials in Process G of FIG. 3A are reduced and the contamination of the surface of the magnetic recording medium 10 can be reduced.

It is preferable that the thickness of the mask layer 3 is generally in a range of 1 to 20 nm.

In addition, in the embodiment, in the case where C is used for the mask layer 3, it may be configured that the mask layer 3 is not removed so as to remain in the later-described Process G and to constitute a portion of the protective carbon layer 9.

Process C, Process D, and Process E

Next, in Process C shown in FIG. 1C, a resist layer 4 is formed on the mask layer 3.

Next, in Process D shown in FIG. 2A, a stamp 5 is allowed to press the resist layer 4 to transfer a negative pattern of the magnetic recording pattern 20.

Next, in Process E shown in FIG. 2B, a portion corresponding to the negative pattern of the magnetic recording pattern 20 in the mask layer 3 is removed.

In the method of manufacturing the magnetic recording medium according to the present invention, as shown in Process D of FIG. 2A, it is preferable that, after the negative pattern of the magnetic recording pattern 20 is transferred to the resist layer 4, a thickness of a concave portion of the resist layer 4 is in a range of 0 to 10 μnm. By setting the thickness of the concave portion in the resist layer 4 to be in the above range, in the etching process for the mask layer 3 indicated by Process E of FIG. 2B, a shear drop of a portion of an edge of the mask layer 3 can be prevented. In addition, the masking property of the mask layer 3 with respect to the milling ions 6 can be improved, and the magnetic recording pattern forming characteristic can be improved by the mask layer 3. In addition, a total thickness of the resist layer 4 is generally in range of about 10 nm to about 100 nm.

In the method of manufacturing the magnetic recording medium according to the present invention, in Process C shown in FIG. 1C and Process D shown in FIG. 2A, it is preferable that a material that is curable by radioactive ray irradiation be used as the material used for the resist layer 4, and the resist layer 4 is irradiated with the radioactive ray at the time of transferring a pattern on the resist layer 4 by using the stamp 5 or after the pattern transferring process. By using the method, a shape of the stamp 5 can be transferred to the resist layer 4 with a high accuracy. Therefore, in the etching process of the mask layer 3 indicated by Process E of FIG. 2B, the shear drop of the portion of the edge of the mask layer 3 is prevented, and the masking property of the mask layer 3 with the respective injected ions can be improved. In addition, the forming characteristic of the magnetic recording pattern 20 can be improved by the mask layer 3. In addition, the radioactive ray described in the embodiment is, for example, an electro-magnetic wave such as a thermal ray of light, a visible ray of light, a ultra-violet ray of light, X-ray of light, or gamma ray of light in a wide sense. In addition, the material that is curable by the radioactive ray irradiation is, for example, a thermosetting resin corresponding to the thermal ray of light and a UV-cured resin corresponding to the ultra-violet ray of light.

In the method of manufacturing the magnetic recording medium according to the present invention, particularly, at the process of transferring the pattern to the resist layer 4 by using the stamp 5, it is preferable that the stamp 5 is allowed to press on the resist layer 4 in the state where the fluidity of the resist layer 4 is high and the resist layer 4 irradiated with the radioactive ray is in the pressed state. Therefore, the resist layer 4 is cured, and after that, the stamp 5 is detached from the resist layer 4, and as a result, the shape of the stamp 5 can be transferred to the resist layer 4 with a high accuracy. As the method of irradiating the resist layer 4 with the radioactive ray in the state where the stamp 5 is allowed to press on the resist layer 4, there is a method of irradiating the radioactive ray from the opposite side of the stamp 5, that is, the side of the non-magnetic substrate 1, a method of selecting a material of transmitting the radioactive ray as the material of the stamp 5 and irradiating the radioactive ray from the side of the stamp 5, a method of irradiating a radioactive ray from the side surface of the stamp 5, a method of using a radioactive ray such as a thermal ray of light having a high conductivity with respect to a solid and irradiating the radioactive ray through thermal conduction from the material of the stamp 5 or the non-magnetic substrate 1, or the like. Among the above methods, in the method of manufacturing the magnetic recording medium according to the present invention, it is preferable that, particularly, a UV-cured resin such as a novolac series resin, an acrylic ester series resin, or an alicyclic epoxy series resin be used as the resist material, and a glass or resin having a high transmittance with respect to the ultra-violet ray of light is used as the material of the stamp 5.

By transferring the pattern to the resist layer 4 by using the aforementioned method, the magnetic characteristics of the boundary area 22 of the magnetic recording pattern 20, for example, the coercive force and the remaining magnetization can be extremely reduced. Therefore, the write fringing at the magnetic recording time can be removed, and a magnetic recording medium having a high surface recording density can be provided.

In addition, as the stamper (stamp 5) used in the above process, a stamper where fine track patterns are formed on a metal plate by using, for example an electron beam lithography method can be used. The material thereof needs to have hardness invulnerable to the process, a durability, and the like. As the material, for example, Ni or the like may be used. However, a material suitable for the aforementioned purpose can be used without limitation in the type of the material. In addition to the tracks where the data are generally recorded, a servo signal pattern such as a burst pattern, a gray code pattern, or a preamble pattern may also be formed in the stamper.

Process F

Next, in Process F shown in FIG. 2C, a portion of the superficial layer of the magnetic layer 2 is removed by ion milling or the like. In the embodiment, by removing a portion of the superficial layer of the magnetic layer 2, the reformation of the magnetic characteristic of a lower portion underlying the magnetic layer 2 can be facilitated by the ion injection in the later-described Process G

In the method of manufacturing the magnetic recording medium according to the present invention, it is preferable that a depth d at the time that a portion of the superficial layer of the magnetic layer 2 is removed by the ion milling or the like is in a range of 0.1 nm to 11 nm. If the depth removed by the ion milling is less than 0.1 nm, the aforementioned magnetic layer removing effect does not occur. In addition, if the depth removed is more than 11 nm, the surface smoothness of the magnetic recording medium deteriorates, and the float property of the magnetic head at the time that the magnetic recording reproducing apparatus is configured may deteriorate.

In addition, in Process F constituting the magnetic recording pattern forming process according to the embodiment, the depth d at the time that a portion of the superficial layer of the aforementioned magnetic layer 2 is removed can be appropriately adjusted. In the embodiment, it is preferable that, by adjusting the removed depth d of the magnetic layer 2, a step difference of a convex-concave portion between the convex portion constituting the magnetic recording area 21 and the concave portion constituting boundary area 22 is formed to be in a range of 0.1 to 11 nm.

Process G

Next, in Process G shown in FIG. 3A, the ion injection is sequentially performed on the portion of the magnetic layer 2 which is removed by ion milling, and the magnetic layer 2 is magnetically separated, and after that, the resist layer 4 and the mask layer 3 are removed by using a dry etching gas Y. In the embodiment, the magnetic recording areas 21 and the boundary areas 22 that magnetically separate servo patterns (not shown) may be formed by performing the ion injection on the magnetic layer 2, which is formed in advance, and by performing the reformation of the magnetic characteristics (deterioration in the magnetic characteristics) of the magnetic layer 2.

In the embodiment, the magnetically separated magnetic recording pattern 20 is formed by processing the continuous magnetic layer 2 that is formed on the non-magnetic substrate 1. More specifically, only the portions of the magnetic layer 2 which are to be magnetic recording areas 21 are provided with the mask layer 3, and with respect to the portions of the magnetic layer 2 which are not covered with the mask layer 3, the upper portions thereof are removed by ion milling, and the reformation of the magnetic characteristics is performed, and thus the lower portions of the portions are changed into a non-magnetic area by ion injection. By using the method, the magnetic recording pattern 20 constructed with the magnetic recording areas 21 (convex portions) and the boundary areas (concave portions) is formed on the magnetic layer 2 to manufacture a discrete track type magnetic recording medium, thereby enabling it to provide a magnetic recording medium having a high surface recording density without the occurrence of write fringing upon magnetic recording.

Herein, the magnetically separated magnetic recording pattern described in the embodiment denotes a state that the magnetic recording areas 21 are separated by non-magnetized boundary areas 22 as viewed from the surface side of the magnetic recording medium 10 as shown in Process G of FIG. 3A. In other words, if the magnetic layer 2 is separated as viewed from the surface side thereof, although the bottom portion of the magnetic layer 2 is not separated, the object of the present invention can be achieved. This case is included in the concept of the magnetically separated magnetic recording pattern described in the embodiment. In addition, the magnetic recording pattern described in the embodiment includes a different servo signal pattern or the like of a patterned medium where the magnetic recording pattern is arranged with a predetermined regularity per one bit or a medium where the magnetic recording pattern is arranged in a track shape. Among them, the manufacturing method according to the embodiment is preferably adapted to a discrete type magnetic recording medium where the magnetically separated magnetic recording pattern is constructed with magnetic recording tracks (magnetic recording areas) and servo signal patterns in terms of simplification of the manufacturing processes.

In addition, the reformation of the magnetic layer 2 for forming the magnetic recording pattern 20 described in the embodiment denotes a partial change in a coercive force, a remaining magnetization, or the like of the magnetic layer 2 so as to pattern the magnetic layer 2, and the change denotes a decrease in the remaining magnetization by decreasing the coercive force.

In addition, in the embodiment, as one method of reforming the portions that magnetically separates the magnetic recording tracks and the servo patterns, there is a method of performing ion injection on the magnetic layer 2 that is formed in advance and allowing the portions of the magnetic layer 2 to be amorphous. In addition, such a method also includes a method of obtaining the reformation of the magnetic characteristics of the magnetic layer 2 by changing the crystalline structure of the magnetic layer 2.

In addition, the process of allowing the magnetic layer 2 to be amorphous described in the embodiment denotes changing the atomic array of the magnetic layer 2 into an irregular atomic array having no long range regularity. More specifically, the process of allowing the magnetic layer to be amorphous denotes changing the atomic array of the magnetic layer 2 into a state that non-crystalline particles having a size of less than 2 nm are randomly arrayed. In addition, in the case where the atomic array state is checked by an analytical method, the state that peaks indicating crystalline planes are not detected but only halos are detected by the X-ray diffraction method or electron beam diffraction method occurs.

In Process G constituting the magnetic recording pattern forming process according to the embodiment, a method of performing ion injection to the magnetic layer 2 may employ a method that has been used in the related art, without any limitation. For example, in the method, a gas such as He, Ne, Ar, Kr, H₂, N₂, CF₄, or SF₆ may be used, and after the gas is ionized, the ionized gas may be accelerated by an electric field to be injected into the surface of the magnetic layer 2.

In addition, in the embodiment, in the case where the process of the ion injection into the magnetic layer 2 performed in Process G is performed with the same ions and conditions as the ion milling described in the aforementioned Process F, these processes may be performed in the same process.

Next, in Process G according to the embodiment, after the ion injection to the magnetic layer 2 is performed, the resist layer 4 and the mask layer 3 are removed. More specifically, for example, a method such as a dry etching method, a reactive ion etching method, an ion milling method, or a wet etching method may be appropriately employed.

In addition, in the case where carbon is used for the mask layer 3, since the carbon can also be used as a protective layer, at least a portion of the mask layer 3 is allowed to remain. In addition, in this case, in the magnetic recording area 21 according to the embodiment, a mask layer 3 that remains on the convex portion constituting the magnetic recording area 21 is not included. In other words, in the method of manufacturing the magnetic recording medium according to the present invention, as described above, although it is preferable that a step difference between the magnetic recording area 21 and the boundary area 22 in a range of 0.1 nm to 11 nm, the thickness of the mask layer 3 that remains on the convex portion (magnetic recording area) is not included in the step difference.

Process H

Next, in the embodiment, as shown in the Process H of FIG. 3B, a boundary area reforming process of oxidizing or nitriding the surface 22a of the boundary area 22 is included.

More specifically, as shown in FIG. 3B, the surface 22a is oxidized or nitrided by irradiating the surface of the magnetic layer 2 with oxygen ions or nitrogen ions (referring to reference numeral X in the figure).

Process I (Protective Layer Forming Process)

Next, as shown in the Process I of FIG. 3C, in the method of manufacturing the magnetic recording medium according to the embodiment, the protective carbon layer 9 is formed.

More specifically, the protective carbon layer 9 is formed on the magnetic layer 2 by using a high-frequency plasma chemical vapor deposition method and by applying a negative bias to the non-magnetic substrate 1. In addition, more preferably, the protective carbon layer 9 is coated with a lubricant.

As a preferable method of forming the protective carbon layer 9, there is generally used a method of forming a thin film of a diamond-like carbon by using a CVD method or the like. However, the method is not particularly limited. In addition, as a CVD apparatus used to form the protective carbon layer 9, an apparatus in the related art can be used without limitation.

Hereinafter, the process of forming the protective carbon layer 9 using a high-frequency plasma chemical vapor deposition method (high-frequency plasma CVD method) is described in detail.

The high-frequency plasma described in the embodiment generally denotes plasma that is generated by applying a power with a frequency of 13.56 MHz to an electrode. However, the frequency is not limited to 13.56 MHz, but it may be appropriately selected in a range of 3 to 30 MHz. In addition, as described above, the bias applied to the non-magnetic substrate 1 is a negative bias, and the voltage may be suitably selected in a range of 100 to 350 V.

In addition, as a source gas used to form the protective carbon layer 9 by using the high-frequency plasma chemical vapor deposition method, a hydrocarbon gas such as methane, ethane, and ethylene, or other gases including carbon, hydrogen, oxygen, nitrogen, or the like may be used.

In the method of manufacturing the magnetic recording medium according to the present invention, the protective carbon layer 9a on the magnetic recording area 21 is formed to be thinner than the protective carbon layer 9b on the boundary area 22.

At the time of forming the protective carbon layer 9 using the aforementioned high-frequency plasma chemical vapor deposition method, a mask layer 3 made of carbon may be allowed to remain on the convex portions constituting the magnetic recording area 21. Otherwise, the mask layer 3 may be allowed to be removed. However, it is preferable that, in any of the methods, there is no damage to the magnetic layer 2 underlying the mask layer 3 due to ion irradiation or the like. In other words, the surface 22a of the concave portions constituting the boundary area 22 is activated by ion milling, and an oxide or nitride of a magnetic material is formed thereon. In this case, the surface 22 has a function in that a probability of attachment of carbon radicals generated by the high-frequency plasma is increased and the thickness of the carbon layer at the associated portion is increased. At this time, the negative bias applied to the non-magnetic substrate 1 has a function of further increasing the probability of attachment of the carbon radicals on a wafer.

On the other hand, in the case where a material having a low probability of attachment of carbon radicals is used as the mask layer 3 that remains on the magnetic recording areas 21 and the mask layer 3 is removed, the surface of the magnetic layer 2 underlying the mask layer 3 is not activated and an oxide or a nitride is not generated.

Therefore, by decreasing the probability of attachment of the carbon radicals on the magnetic recording areas 21 of the magnetic layer 2, the protective carbon layer 9a on the convex portions constituting the magnetic recording areas 21 is formed to be thinner than the protective carbon layer 9b on the concave portions constituting the boundary areas 22.

In addition, in the embodiment, in Process H, after the surface 22a of the concave portion constituting the boundary area 22 is oxidized or nitrided, the protective carbon layer 9 is formed by using the high-frequency plasma chemical vapor deposition method, and therefore the selective growth of the aforementioned protective carbon layer 9 can be promoted. In addition, in a method, the milling ions 6 may include oxygen or nitrogen in the aforementioned Process G of forming the boundary areas 22 in the magnetic recording pattern 20, and the aforementioned Process H of oxidizing or nitriding the surface 22a of the boundary areas 22 may be provided after Process G. As important points in the processes, the surface of the mask layer 3 is not in the activated state, and the probability of attachment of the carbon radicals with respect to the portions of the mask layer 3 is not increased.

Although detailed illustration is omitted, the high-frequency plasma CVD layer forming apparatus that is a main component of a manufacturing apparatus used in the method of manufacturing the magnetic recording medium according to the embodiment may include, for example, a chamber that receives a disk (wafer), electrodes that are disposed on two side surfaces of the chamber to face each other, a high-frequency power source that supplies a high-frequency power to the electrodes, a bias power source that can be connected to the disk in the chamber, and a reactive gas supplying source that supplies a reactive gas as a source material for the protective carbon layer to be formed on the disk. In addition, an introducing pipe for introducing the reactive gas into the chamber and a discharging pipe for discharging the gas in the chamber to an outer side of system are connected to the aforementioned chamber. In addition, the discharging pipe is provided with a discharging amount regulating valve to regulate a discharging amount, and accordingly an internal pressure of the chamber can be set to an arbitrary value.

As a preferable high-frequency power source used for the aforementioned high-frequency plasma CVD layer forming apparatus, a high-frequency power source capable of supplying a power of 50 to 2000 W to the electrode at the time of forming the protective carbon layer 9 is used. In addition, as a preferable bias power source that applies the bias to the non-magnetic substrate 1, a DC power source is used, and a power source capable of applying a power of 10 to 300 W to the disk is used. In addition, as a preferable high-frequency power source, a pulsed DC power source is used. In this case, it is preferable that, a pulse width is in a range of 10 to 50000 ns, a frequency is in a range of 10 kHz to 10 MHz, and a voltage (average voltage) of −350 to −10 V is applied to the disk.

In addition, in Process I (protective layer forming process), it is preferable that a step difference of a convex-concave portion between the magnetic recording area 21 and the boundary area 22 on the surface 91 of the protective carbon layer 9, that is, a step difference h between the position of the protective carbon layer 9a and the position of the protective carbon layer 9b be formed in a range of 0 to 11 nm. If the step difference of the surface 91 of the protective carbon layer 9 is in this range, the surface smoothness of the protective carbon layer 9 and the magnetic recording medium 10 is improved.

In addition, in the embodiment, it is preferable that, a lubricating layer (not shown) that is made of, for example, a fluorine series lubricant, a hydrocarbon series lubricant, or a mixture thereof be formed on the protective carbon layer 9. In addition, in this case, it is preferable that the thickness of the lubricating layer be in a range of 1 to 4 nm similarly to a lubricating layer generally formed on a magnetic recording medium.

Hereinafter, a relationship between a step difference of a convex-concave portion between the magnetic recording area 21 and the boundary area 22 and a step difference of a convex-concave portion between the protective carbon layer 9a formed on the magnetic recording area 21 and the protective carbon layer 9b formed on the boundary area 22 is described with reference to FIGS. 4A to 4C. FIGS. 4A to 4C are diagrammatic views for explaining an example of forming the protective carbon layer on the magnetic layer by using various layer formation methods.

In the case where the magnetic recording medium is manufactured by the manufacturing method according to the embodiment, as shown in FIGS. 4A to 4C, convex-concave portions are formed on the surface of the magnetic layer 2 (120) by the magnetic recording areas 21 (121) constructed with convex portions and the boundary areas 22 (122) constructed with concave portions. The convex-concave portions are formed by performing the ion milling and the ion injection on the portions of the boundary areas 22 (122) in the magnetic layer 2 (120) that is sequentially formed. In the case where the protective carbon layer 90 is formed on the magnetic layer 2 (120) having the step difference of convex-concave portions by using a PVD method (physical vapor deposition method) in the related art, as shown in FIG. 4A, the thickness of the protective carbon layer 90 on the convex portion is equal to that on the concave portion. For this reason, the protective carbon layer 90 has a convex-concave portion surface of which the depth is substantially equal to that of the underlying magnetic layer 2 (120), accordingly the surface smoothness of the magnetic recording medium is decreased.

On the contrary, as shown in FIG. 4B, in the case where the protective carbon layer 9 is formed on the magnetic layer 2 having the aforementioned step difference of the convex-concave portion by using the high-frequency plasma chemical vapor deposition method according to the conditions specified in the present invention, the protective carbon layer 9a on the concave portion (boundary area 22) is formed to be thinner than the protective carbon layer 9b on the convex portion (magnetic recording area 21). Therefore, the step difference of a convex-concave portion formed on the surface of the magnetic layer 2 is alleviated by the protective carbon layer 9, accordingly the surface smoothness of the magnetic recording medium 10 can be increased.

On the other hand, as shown in FIG. 4C, the protective carbon layer 19a on the magnetic recording area 121 may be formed to be thicker than the protective carbon layer 19b on the boundary area 122. This is because the convex portion constituting the magnetic recording area 121 is located at the position near the plasma space in the chamber, accordingly the probability of attachment of the carbon radicals to the associated positions is increased, and as a layer forming characteristic of the CVD method, there is influence resulting in an increase in the growth speed of the convex portion.

In the magnetic recording medium obtained by the method of manufacturing the magnetic recording medium according to the present invention, as shown in FIG. 4B, in the cross section in the perpendicular direction with respect to the surface of the magnetic recording medium, the convex portions are formed on the surface of the magnetic recording area 21, and the concave portions are formed on the surface of the boundary area 22. In addition, the thickness t1 of the protective carbon layer 9a on the magnetic recording area 21 is smaller than the thickness t2 of the protective carbon layer 9b on the boundary area 22. In addition, in the embodiment, it is preferable that a step difference between the convex portion and the concave portion be in a range of 0.1 nm to 9 nm, and a step difference h of the surface of the protective carbon layer 9 be in a range of 0 nm to 11 nm. In addition, it is preferable that the thickness of the protective carbon layer 9a on the magnetic recording area 21 be in a range of 1 nm to 5 nm. In addition, it is preferable that the thickness of the protective carbon layer 9b on the boundary area 22 be in a range of 0.1 nm to 4 nm. In the embodiment, by setting the thickness of the protective carbon layer provided to the magnetic recording medium to be in the aforementioned range, it is possible to manufacture a magnetic recording medium having an excellent float property of the magnetic head and an excellent electro-magnetic conversion characteristic when the magnetic recording medium is used for a magnetic recording reproducing apparatus.

As described above, according to the method of manufacturing the magnetic recording medium according to the embodiment, since the method is a method including the magnetic recording pattern forming process of forming the magnetic recording areas 21 that are constructed with the convex portions and the boundary areas 22 that are constructed with the concave portions between the magnetic recording areas 21 as the magnetic recording pattern 20 on the magnetic layer 2, followed by the protective layer forming process of forming the protective carbon layer 9 using the high-frequency plasma chemical vapor deposition method while applying a negative bias to the non-magnetic substrate 1 to make the protective carbon layer 9a on the magnetic recording area 21 thinner than the protective carbon layer 9b on the boundary area 22, the convex-concave portions formed on the magnetic recording pattern 20 can be efficiently smoothed. In addition, since the protective carbon layer 9 used for the smoothing is directly used as a protective layer for the magnetic recording medium, it is possible to greatly simplify the manufacturing processes. Therefore, the magnetic recording medium 10 having an excellent surface smoothness can be manufactured with a high productivity.

In addition, with respect to the magnetic recording medium 10 that is obtained according to the manufacturing method according to the present invention, the production cost can be reduced, and the sufficient recording reproducing characteristics can be ensured, accordingly the magnetic recording medium 10 can be adapted to a high recording density.

[Magnetic Recording Reproducing Apparatus]

Next, a configuration of a magnetic recording reproducing apparatus (hard disk drive) according to the present invention is shown in FIG. 5. As shown in FIG. 5, the magnetic recording reproducing apparatus 50 includes the aforementioned magnetic recording medium 10, a medium driving unit 51 that drives the medium in a recording direction, a magnetic head 57 that is constructed with a recording unit and a reproducing unit, a head driving unit 58 that relatively moves the magnetic head 57 with respect to the magnetic recording medium 10, and a recording reproducing signal system 59 that has a recording reproducing signal means for inputting signals to the magnetic head 57 and reproducing signals output from the magnetic head 57. The magnetic recording reproducing apparatus 50 having a high recording density can be configured by combination of the aforementioned components. In the present invention, the recording tracks of the magnetic recording medium 10 are processed magnetically in a non-continuous manner, accordingly the reproducing head width and the recording head width can be allowed to equal to each other unlike the related art where the reproducing head width is formed to be smaller than the recording head width in order to avoid the influence of the magnetization transition area of the track edge portion. Accordingly, it is possible to implement the magnetic recording reproducing apparatus 50 having a sufficient reproducing output and a high SNR.

In addition, in the embodiment, by constructing the reproducing unit of the aforementioned magnetic head 57 with a GMR head or a TMR head, sufficient signal intensity can be obtained even in the case of the high recording density, accordingly it is possible to implement a magnetic recording reproducing apparatus having a high recording density. In addition, by setting the floating amount of the magnetic head 57 to be in a range of 0.005 μm to 0.020 μm, namely by floating it at a lower height than before, the power can be improved and a high apparatus SNR can be obtained, accordingly it is possible to provide a magnetic recording reproducing apparatus having a large capacity and a high reliability. In addition, in the case where a signal process circuit according to a maximum likelihood decoding method is assembled, the recording density can be further improved. Accordingly to the configuration, even in the case where the recording and reproducing are performed with a track density of 100 k tracks/inch or more, a linear recording density of 1000 kbits/inch or more, and a recording density of 100 Gbits/square inch, a sufficient SNR can be obtained.

### EXAMPLES

Next, the method of manufacturing the magnetic recording medium according to the present invention, the magnetic recording medium, and the magnetic recording reproducing apparatus are described by using Examples and Comparative Examples, but the present invention is not limited to the Examples.

### Example

First, a vacuum chamber where a HD glass substrate is set is evacuated in a vacuum of 1.0×10⁻⁵ Pa or less in advance. At this time, as the glass substrate, a material made of a crystalline glass containing Li₂Si₂O₅, Al₂O₃—K₂O, MgO—P₂O₅, or Sb₂O₃—ZnO as a constituent is used. A glass substrate having an outer diameter of 65 mm, an inner diameter of 20 mm, and an average surface roughness (Ra) of 2 angstroms is used.

Next, 65Fe-30Co-5B as the soft magnetic layer, Ru as the intermediate layer, and granular structured vertically-aligned 92(70Co-10Cr-20Pt)-8SiO₂ (mole ratio) alloy and 60Co-16Cr-16Pt-8B alloy as thin films of the magnetic layer are formed in this order on the glass substrate by using a DC sputtering method. With respect to the thicknesses of the layers, the thickness of the FeCoB soft magnetic layer is set to 60 nm; the thickness of the Ru intermediate layer is set to 10 nm; the thicknesses of the thin films of the magnetic layer are set to 10 nm and 5 nm.

Next, a mask layer is formed thereon by using a sputtering method. As a material for the mask layer, C (carbon) is used. The thickness thereof is set to 60 nm.

Next, a resist layer is coated thereon by using a spin coat method. At this time, as the resist layer, a novolac series resin that is a UV cured resin is used. The thickness thereof is set to 100 nm.

Next, a stamp made of a glass having a negative pattern of the magnetic recording pattern is used and the stamp is allowed to press on the resist layer with a pressure of 1 MPa (about 8.8 kgf/cm²). Next, in this state, the resist layer is irradiated for 10 seconds with ultra-violet ray of light having a wavelength of 250 nm from the upper portion of the glass stamp of which the transmittance with respect to the ultra-violet ray of light is 95% or more, accordingly the resist layer is cured. Next, the stamp is detached from the resist layer, and the magnetic recording pattern is transferred to the resist layer. Herein, with respect to the magnetic recording pattern transferred to the resist layer, the convex portion of the resist layer has a cylindrical shape with a width of 120 nm; the concave portion of the resist layer has a cylindrical shape with a width of 60 nm; the thickness of the resist layer is 80 nm; and the thickness of the bottom portion of the concave portion of the resist layer is about 5 nm. In addition, an angle of the concave portion of the resist layer with respect to the surface of the substrate (surface of the wafer) is substantially 90 degrees.

Next, the portions of the concave portions of the resist layer and the C layer (mask layer) underlying thereof are removed by dry etching. In this case, as the dry etching conditions, a flow rate of the O₂ gas is set to 40 sccm; a pressure thereof is set to 0.3 Pa; a high-frequency plasma power is set to 300 W; a DC bias is set to 30 W; and an etching time is set to 30 seconds.

Next, with respect to the portions of the magnetic layer that are not covered with the mask layer, the surface thereof is removed by ion milling. In this case, Ar ions are used for the ion milling, and a depth of a removed portion of the magnetic layer is 4 nm. In addition, as the conditions of the ion milling, a high-frequency irradiation power is set to 800 W; an acceleration voltage is set to 500 V; a pressure is set to 0.012 Pa; a flow rate of Ar is set to 5 sccm; and a current density is set to 0.4 mA/cm². By performing the ion milling, a portion down to a depth of 8 nm below the portions of the magnetic layer that are subjected to the milling can be demagnetized.

Next, a portion of the resist layer and a portion of the mask layer are removed by dry etching. In this case, as the conditions of the dry etching, a flow rate of the oxygen gas is set to 100 sccm; a pressure thereof is et to 2.0 Pa; a high-frequency plasma power is set to 400 W; and a processing time is set to 300 seconds, accordingly the mask layer with only the thickness of 1 nm in the thickness direction is allowed to remain.

Next, by forming a protective carbon layer that is made of a carbon material (DLC; diamond-like carbon) by using a high-frequency plasma CVD method on the surface of the magnetic layer, the magnetic recording medium is manufactured. In this case, the layer forming process is performed by using a high-frequency plasma CVD apparatus with the conditions of an applying power of 800 W at a frequency of 13.56 MHz, a source gas of ethylene, and a layer forming time of 10 seconds. In addition, at the time of forming the protective carbon layer, a DC voltage of −220 V as a bias is applied to the non-magnetic substrate. In addition, the thickness of the protective carbon layer on the magnetic recording area is 3 nm, and a step difference between the convex portion and the concave portion is 3 nm.

Next, electro-magnetic conversion characteristics (SNR and 3T-squash) of the magnetic recording medium manufactured according to the aforementioned method are measured by a spin standard. In this case, with respect to the test magnetic head, a vertical recording head is used as a recording head, and a TuMR head is used as a reading head. In the case where a signal of 750 kFCI is recorded, the SNR value and the 3T-squash are measured.

As a result of the measurement, in the magnetic recording medium manufactured according to the manufacturing method according to the present invention, the SNR is 13.4 dB, the 3T-squash is 87%, and the float property of the magnetic head is stabilized. Therefore it can be confirmed that the electro-magnetic conversion characteristics are excellent.

[Comparative Example 1]

A magnetic recording medium of Comparative Example 1 is manufactured according to the same procedure as the aforementioned Example except that the protective carbon layer is formed on the surface of the magnetic layer by a magnetron sputter apparatus using a 6-inch carbon target and an applying power of 1500 W. In the magnetic recording medium of Comparative Example 1 that is obtained by the procedure, a protective carbon layer of 5 nm is formed on the convex portion of the magnetic layer, and a protective carbon layer of 5 nm is also formed on the concave portion, and the step difference is 5 nm.

Next, the electro-magnetic conversion characteristics of the magnetic recording medium of Comparative Example 1 that is manufactured by the aforementioned procedure are measured by the same method as the aforementioned Example. As a result of the measurement, the SNR is 12.2 dB, and the 3T-squash is 75%. Therefore, it can be clarified that the electro-magnetic conversion characteristics are lowered in comparison with the magnetic recording medium of the aforementioned Example.

### [Comparative Example 2]

A magnetic recording medium of Comparative Example 2 is manufactured according to the same procedure as the aforementioned Example except that the DC voltage bias is not applied to the non-magnetic substrate to form the protective carbon layer. In the magnetic recording medium of Comparative Example 2 that is obtained by the procedure, the protective carbon layer of 5 nm is formed on the convex portion of the magnetic layer, and the protective carbon layer of 5 nm is also formed on the concave portion, and the step difference is 5 nm.

Next, the electro-magnetic conversion characteristics of the magnetic recording medium of Comparative Example 2 that is manufactured by the aforementioned procedure are measured by the same method as the aforementioned Example. As a result of the measurement, the SNR is 12.3 dB, and the 3T-squash is 76%. Therefore, it can be clarified that the electro-magnetic conversion characteristics are lowered in comparison with the magnetic recording medium of the aforementioned Example.

[Comparative Example 3]

A magnetic recording medium of Comparative Example 3 is manufactured according to the same procedure as the aforementioned Example except that the DC voltage bias applied to the non-magnetic substrate is set to +200 V. In the magnetic recording medium of Comparative Example 3that is obtained by the procedure, the protective carbon layer of 7 nm is formed on the convex portion of the magnetic layer, and the protective carbon layer of 4 nm is also formed on the concave portion, and the step difference is 8 nm.

Next, the electro-magnetic conversion characteristics of the magnetic recording medium of Comparative Example 3 that is manufactured by the aforementioned procedure are measured by the same method as the aforementioned Example. As a result of the measurement, the SNR is 12.0 dB, and the 3T-squash is 73%. Therefore, it can be clarified that the electro-magnetic conversion characteristics are greatly lowered in comparison with the magnetic recording medium of the aforementioned Example.

According to the above results, it can be understood that, according to a method of manufacturing a magnetic recording medium according to the present invention, a magnetic recording medium having an excellent surface smoothness can be manufactured with a high productivity. In addition, it can be understood that the magnetic recording medium obtained according to the manufacturing method can ensure sufficient recording reproducing characteristics, and the magnetic recording medium can be adapted to a high recording density.

While the present invention has been particularly shown and described with reference to exemplary embodiments thereof, the present invention is not limited to the exemplary embodiments. It will be understood by those skilled in the art that additions, omissions, replacements, and other modifications of configuration can be made therein without departing from the spirit and scope of the present invention. The present invention is not limited to the above description, but it is limited only by the appended claims.

1. A method of manufacturing a magnetic recording medium where at least a magnetic layer is formed on a non-magnetic substrate and a magnetically separated magnetic recording pattern is formed on the magnetic layer, comprising:
a magnetic recording pattern forming process of forming magnetic recording areas that are constructed with convex portions and boundary areas that are constructed with concave portions between the magnetic recording area as the magnetic recording pattern on the magnetic layer; followed by
a protective layer forming process of forming a protective carbon layer by using a high-frequency plasma chemical vapor deposition method and by applying a negative bias to the non-magnetic substrate to make the protective carbon layer on the magnetic recording area thinner than the protective carbon layer on the boundary area.

2. The method of manufacturing a magnetic recording medium according to claim 1, further comprising a boundary area reforming process of oxidizing or nitriding a surface of the boundary area between the magnetic recording pattern forming process and the protective layer forming process.

3. The method of manufacturing a magnetic recording medium according to claim 1, wherein in the magnetic recording pattern forming process, the boundary area is formed as a non-magnetic area.

4. The method of manufacturing a magnetic recording medium according to claim 1, wherein in the magnetic recording pattern forming process, the boundary area is formed by performing ion milling and ion injection on the magnetic layer.

5. The method of manufacturing a magnetic recording medium according to claim 1, wherein in the magnetic recording pattern forming process, a step difference of a convex-concave portion between the magnetic recording area and the boundary area is formed in a range of 0.1 to 9 nm.

6. The method of manufacturing a magnetic recording medium according to claim 1, wherein in the protective layer forming process, a step difference of a convex-concave portion between the magnetic recording area and the boundary area on a surface of the protective carbon layer is formed in a range of 0 to 11 nm.

7. A magnetic recording medium manufactured by the method of manufacturing a magnetic recording medium according to claim 1.

8. A magnetic recording reproducing apparatus comprising:
the magnetic recording medium according to claim 7;
a driving unit that drives the magnetic recording medium in a recording direction;
a magnetic head that is constructed with a recording unit and a reproducing unit;
a means for relatively moving the magnetic head with respect to the magnetic recording medium; and
a recording reproducing signal processing means for inputting signals to the magnetic head and reproducing signals output from the magnetic head.
